(19) United States
(12) Patent Application Publication
(10) Pub. No.: US 2015/0070829 A1
(43) Pub. Date: Mar. 12, 2015

(54) SERVER WITH SUPPORTING BRACKET

(71) Applicants: HON HAI PRECISION INDUSTRY CO., LTD., New Taipei (TW); HONG FU JIN PRECISION INDUSTRY (ShenZhen) Co., LTD., Shenzhen (CN)

(72) Inventors: WAN-LI NING, Shenzhen (CN); AI-LING HE, Shenzhen (CN); LEI LIU, Shenzhen (CN); AN-GANG LIANG, Shenzhen (CN); PING-CHUAN DENG, Shenzhen (CN)

(73) Assignees: HON HAI PRECISION INDUSTRY CO., LTD., New Taipei (TW); HONG FU JIN PRECISION INDUSTRY (ShenZhen) Co., LTD., Shenzhen (CN)

(21) Appl. No.: 14/037,399

(22) Filed: Sep. 26, 2013

(30) Foreign Application Priority Data
Sep. 11, 2013 (CN) 2013104107732

(51) Int. Cl. H05K 7/20

(52) U.S. Cl. CPC H05K 7/20736
USPC 361/679.33; 454/184

(57) ABSTRACT

A supporting bracket includes two opposite sidewalls, a first end wall connected between front ends of the sidewalls, a second end wall connected between rear ends of the sidewalls, and an air guiding plate slantingly connected between lower parts of the sidewalls. The air guiding plate extends up from the first end wall toward the second end wall. A top of the air guiding plate and the sidewalls bound a cooling area communicating with an inside of the supporting bracket. An air inlet of the cooling area is defined between the first end wall and the air guiding plate.

### BACKGROUND

1. Technical Field

The present disclosure relates to servers, and particularly to a server having a supporting bracket.

2. Description of Related Art

Servers may have a rack containing a large number of hard disk drives. A number of exhaust fans are positioned at a rear end of the rack to blow heat generated by the hard disk drives out of the rack. However, heat generated by the hard disk drives located at a front end of the rack is drawn to the hard disk drives located at the rear end of the rack. Thus, the hard disk drives located at the rear end are heated up by the heat from the hard disk drives located at a front end, which will diminish the efficiency of heat dissipation.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an assembled, isometric view of an exemplary embodiment of an electronic device, wherein the electronic device includes a plurality of supporting brackets.

FIG. 2 is an exploded view of one of the supporting brackets of FIG. 1.

FIG. 3 is similar to FIG. 2, but viewed from another aspect.

FIG. 4 is a cross-sectional view of FIG. 1, taken along line IV-IV.

FIG. 5 is similar to FIG. 4, but showing the electronic device in a state of use.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at “least one.”

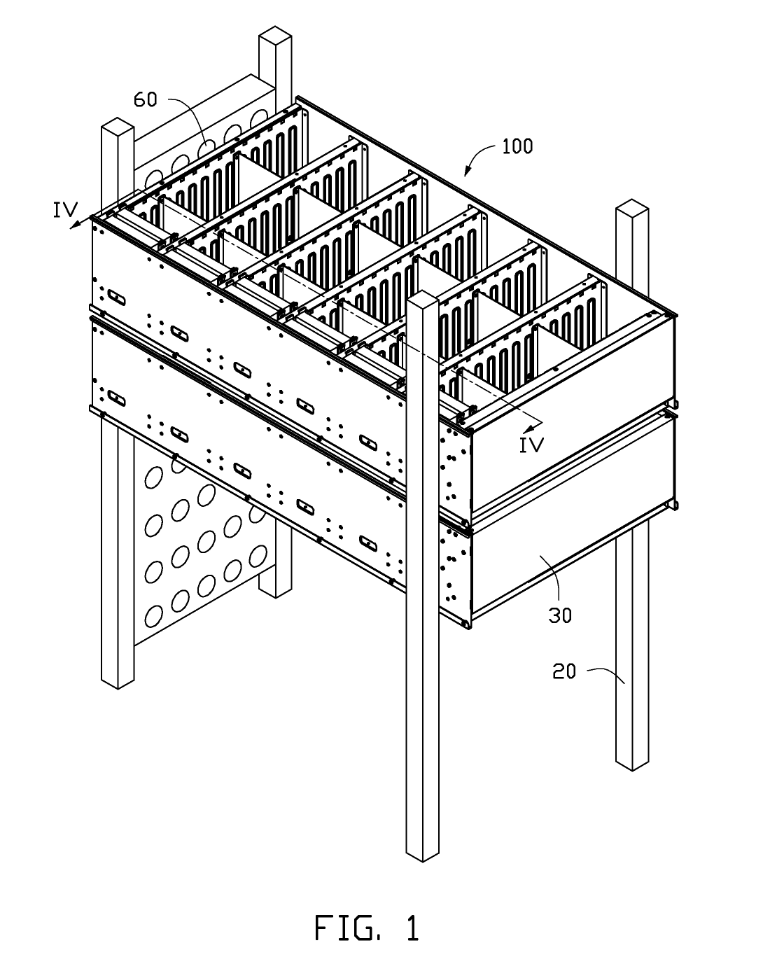

FIG. 1 shows an exemplary embodiment of an electronic device 100. The electronic device 100 includes a rack 20, a plurality of storage modules 30 stacked on top of each other in the rack 20, and a plurality of exhaust fans 60 positioned at a rear end of the rack 20.

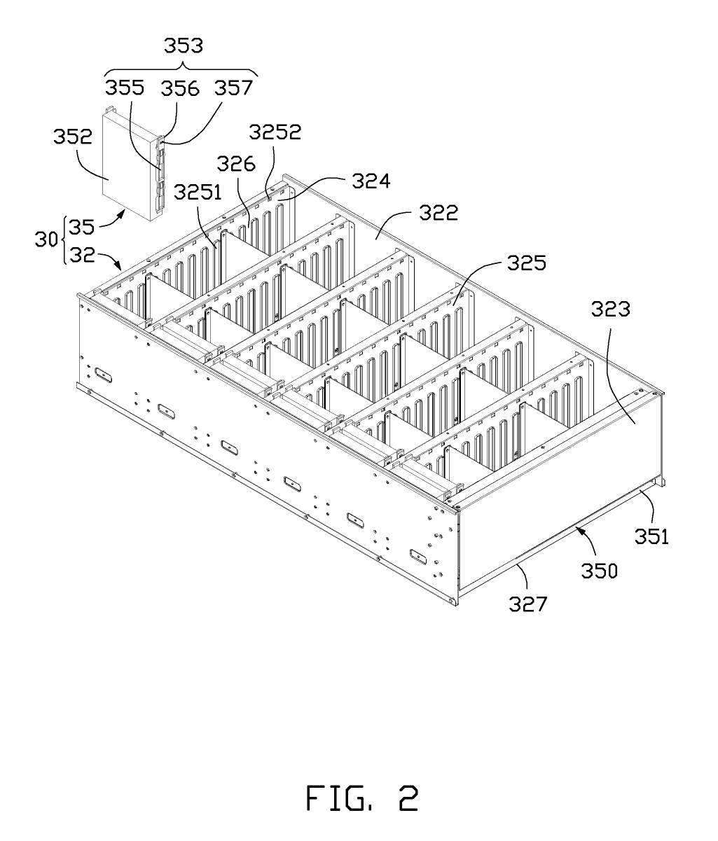

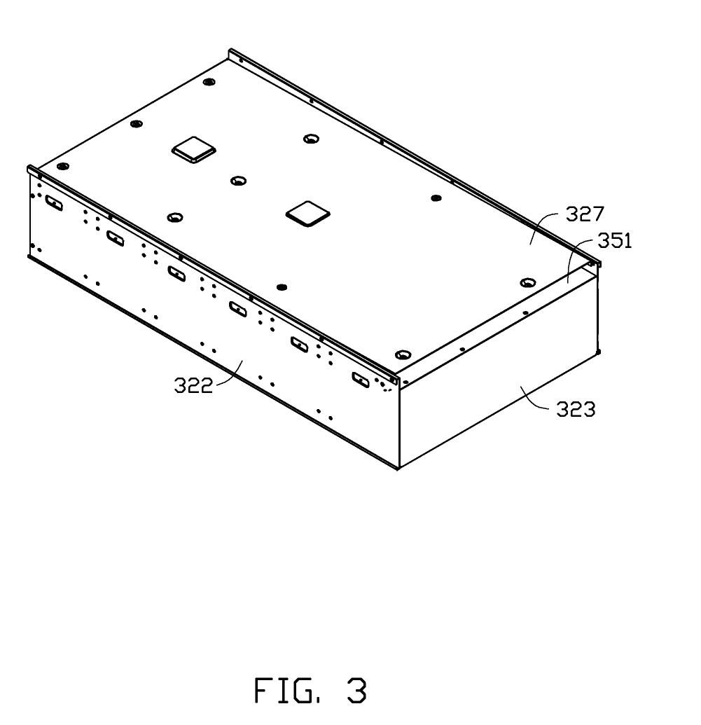

FIGS. 2 and 3 show that a storage module 30 includes a supporting bracket 32 and a plurality of hard disk drives 35 installed in the supporting bracket 32.

The supporting bracket 32 includes two opposite sidewalls 322, a first end wall 323 connected substantially perpendicularly between front ends of the sidewalls 322, a second end wall 324 connected substantially perpendicularly between rear ends of the sidewalls 322, a plurality of supporting walls 325 connected substantially perpendicularly between the sidewalls 322, and an air guiding plate 327. The supporting walls 325 are substantially parallel to the first and second end walls 323 and 324. The supporting bracket 32 is divided into a plurality of receiving spaces 326 by the supporting walls 325. A plurality of pairs of oppositely facing positioning bars 3251 is formed on the supporting walls 325, the first end wall 323, and the second end wall 324. The pairs of positioning bars 3251 protrude toward the receiving spaces 326. Each of the supporting walls 325, the first end wall 323, and the second end wall 324 define a plurality of latching holes 3252 above the positioning bars 3251. The air guiding plate 327 is slantingly connected between lower parts of the sidewalls 322 and is located below the first and second end walls 323 and 324. The air guiding plate 327 extends up from the first end wall 323 toward the second end wall 324. A top of the air guiding plate 327, the sidewalls 322, and bottoms of the supporting walls 325 cooperatively define a trapezoidal cooling area 350 communicating with the receiving spaces 326 of the supporting bracket 30. An air inlet 351 is defined between the first end wall 323 and the air guiding plate 327. A height of the cooling area 350 gradually decreases from the first end wall 323 to the second end wall 324.

Each hard disk drive 35 includes a main body 352 and two latching members 353 mounted on opposite ends of the main body 352, respectively. An outer surface of each latching member 353 longitudinally defines a positioning slot 355. A resilient operation piece 356 extends up from a top end of the latching member 353. A latching block 357 protrudes out from the operation piece 356.

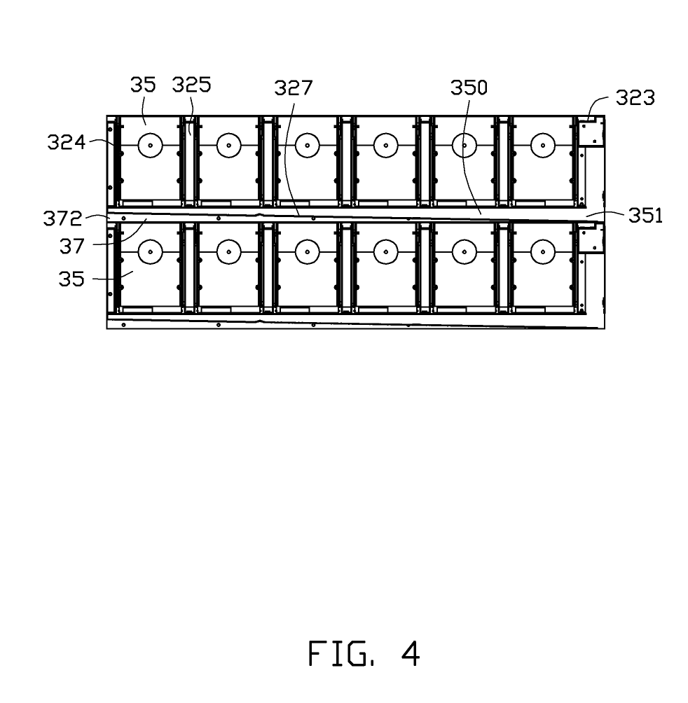

FIG. 4 shows two overlapping storage modules 30. The air guiding plate 327 of the upper storage module 30 and a top of the lower storage module 30 cooperatively define a trapezoidal airflow channel 37 communicating with the receiving spaces 326 of the lower storage module 30. An air outlet 372 is defined between the second end wall 324 of the lower storage module 30 and the air guiding plate 327 of the upper storage module 30. A height of the airflow channel 37 gradually increases from the first end wall 323 to the second end wall 324.

The exhaust fans 60 are mounted to the rack 20 to align with the air outlets 372 of the storage modules 30.

In assembly of each storage module 30, a plurality of hard disk drives 35 is received in a corresponding receiving space 326, such that the positioning slots 355 align with the corresponding positioning bars 3251. The hard disk drive 35 is pressed down, the latching blocks 357 slidably abut against the supporting walls 325, and the operation pieces 356 are deformed until the latching blocks 357 align with the corresponding latching holes 3252. The operation pieces 356 are restored to bias the latching blocks 357 to latch in the latching holes 3252, and the positioning bars 3251 latch in the positioning slots 355.

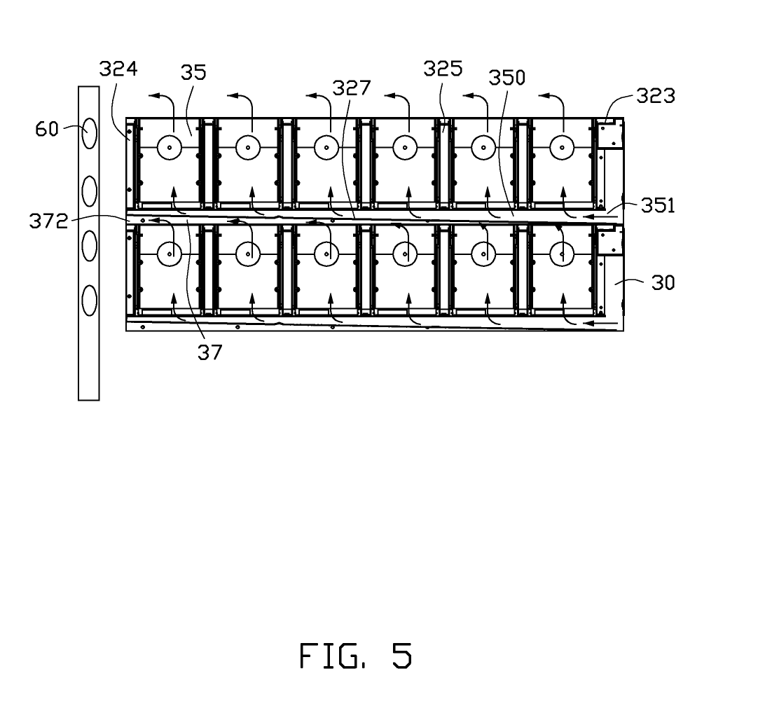

FIG. 5 shows that in use, the exhaust fans 60 generate an airflow flowing into the cooling areas 350 from the air inlets 351. The airflow flows up through the hard disk drives 35 from the cooling area 350. The airflow absorbs heat generated by the hard disk drives 35, and the exhaust fans 60 blow the heat out of the supporting brackets 32 from the airflow channels 37 and the air outlets 372.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A supporting bracket, comprising:
two opposite sidewalls;
a first end wall connected between front ends of the sidewalls;
a second end wall connected between rear ends of the sidewalls; and
an air guiding plate slantingly sandwiched between lower parts of the sidewalls, and located below the first and second end walls;
wherein the air guiding plate extends up from the first end wall toward the second end wall, a top of the air guiding plate and the sidewalls bound a cooling area communicating with inside of the supporting bracket, an air inlet of the cooling area is defined between the first end wall and the air guiding plate.

2. The supporting bracket of claim 1, further comprising a plurality of spaced supporting walls connected between the sidewalls and parallel to the first and second end walls, the plurality of supporting walls divides the supporting bracket into a plurality of receiving spaces.

3. The supporting bracket of claim 2, wherein a plurality pairs of positioning bars protrudes toward the plurality of receiving spaces from the plurality of supporting walls, and the first and second end walls.

4. The supporting bracket of claim 3, wherein the first end wall, the second end wall, and the plurality of supporting walls define a plurality of latching holes above the plurality of positioning bars.

5. The supporting bracket of claim 2, wherein the cooling area is trapezoidal and below the plurality of supporting walls, a height of the cooling area gradually reduces from the first end wall toward the second end wall.

6. An electronic device comprising:
a rack;
a plurality of supporting brackets overlapped in the rack; and
a plurality of hard disk drives mounted in each supporting bracket, wherein each supporting bracket comprises:
two opposite sidewalls;
a first end wall connected between front ends of the sidewalls;
a second end wall connected between rear ends of the sidewalls; and
an air guiding plate slantingly sandwiched between lower parts of the sidewalls and located below the first and second end walls, and extending up from the first end wall toward the second end wall;
wherein a top of the air guiding plate and the sidewalls of each supporting bracket bound a cooling area communicating with inside of the supporting bracket, an air inlet of the cooling area is defined between the first end wall and the air guiding plate of each supporting bracket, the air guiding plate of each of the plurality of supporting brackets and a top of a lower supporting bracket cooperatively bound an airflow channel communicating with inside of the lower supporting bracket, an air outlet of the airflow channel is defined between the second end wall of the lower supporting bracket and the air guiding plate of the supporting bracket.

7. The electronic device of claim 6, wherein each supporting bracket further comprises a plurality of spaced supporting walls connected between the sidewalls and parallel to the first and second end walls, the plurality of supporting walls divides the supporting bracket into a plurality of receiving spaces, the plurality of hard disk drives is received in the plurality of receiving spaces.

8. The electronic device of claim 7, wherein a plurality pairs of positioning bars protrudes toward the plurality of receiving spaces from the plurality of supporting walls, and the first and second end walls, each hard disk drive comprises a main body and two latching members mounted on two opposite sides of the main body, the latching members are detachably latched to the corresponding positioning bars.

9. The electronic device of claim 8, wherein the first end wall, the second end wall, and the plurality of supporting walls define a plurality of latching holes above the plurality of positioning bars, each latching member comprises a resilient operation piece extending up from a top of the latching member and a latching block protruding out from the operation piece, the latching block of each latching member is detachably latched in the corresponding latching hole.

10. The electronic device of claim 6, wherein each cooling area is trapezoidal, a height of the cooling area gradually reduces from the first end wall toward the second end wall.

11. The electronic device of claim 6, wherein each airflow channel is trapezoidal, a height of the airflow channel gradually increases from the first end wall toward the second end wall.

12. The electronic device of claim 6, further comprising a plurality of exhaust fans mounted to the rack and aligning with the air outlets.
